(19) United States
(12) Patent Application Publication
(10) Pub. No.: US 2012/0087092 A1
(43) Pub. Date: Apr. 12, 2012

(54) COOLING MEDIUM LINE INTERCONNECTION FOR ACHIEVING VERY UNIFORM COOLING TEMPERATURS AND HIGH AVAILABILITY PARTICULARLY OF POWER MACHINES

(75) Inventors: Norbert Huber, Erlangen (DE); Michael Meinert, Erlangen (BE); Armin Rastogi, Hagenbuchach (DE); Karsten Rechenberg, Dormitz (DE)

(73) Assignee: SIEMENS AKTIENGESELLSAFT, Munich (DE)

(21) Appl. No.: 13/377,634

(22) PCT Filed: Apr. 27, 2010
(86) PCT No.: PCT/EP2010/055585

§ 371 Date: Dec. 12, 2011

(30) Foreign Application Priority Data
Jun. 10, 2009 (DE) 10 2009 024 579.0

(51) Int. Cl. H05K 7/20

(52) U.S. Cl. 361/701

(57) ABSTRACT

A uniform temperature of the machines to be cooled is obtained by way of a device for cooling at least one power component. The device has a cooling medium line, a cooling medium pump and a heat exchanger. Furthermore, streams of cooling media are to be kept low. A return runs back in the direction of an inlet along a flow up to an outlet. In this way, a counter stream interconnection for averaging a flow and a return temperature of a cooling medium is achieved.

### CROSS REFERENCE TO RELATED APPLICATIONS

This application is based on and hereby claims priority to International Application No. PCT/EP2010/055585 filed on Apr. 27, 2010 and German Application No. 10 2009 024 579.0 filed on Jun. 10, 2009, the contents of which are hereby incorporated by reference.

### BACKGROUND

For cooling of power machines a cooling plate, which dissipates the heat arising to a fluid cooling medium, is typically attached to a cooling surface. The fluid cooling medium can be a cooling liquid or a cooling gas. As it flows through this cooling plate the cooling medium heats up, which results in cooling being greater in the area of the entry than at the exit. FIG. 1 presents a conventional exemplary embodiment for cooling a power machine. A similar problem occurs in the case of sequential cooling of a plurality of power components. Here, the component that lies at the end of the cooling path is the worst cooled. FIG. 2 presents a conventional exemplary embodiment of a device for cooling a plurality of components. The result of such uneven cooling is on the one hand an uneven temperature of the elements to be cooled. This leads under some circumstances to different electrical properties, with dual-layer capacitors for example. A further disadvantage is the requirement for very large cooling medium flows since cooling has to be designed for the most unfavorable location.

Conventionally these disadvantages are taken into account. The cooling medium flows are designed to be very large. In the case of a system of a plurality of power components, a plurality of cooling paths are needed, which demands a greater outlay in piping and which makes it necessary to match the cooling runs to each other, by regulating valves for example.

### SUMMARY

One possible object is to provide a device for cooling of components, especially power machines, with a fluid cooling medium or coolant, so as to bring about an even temperature of the machine to be cooled. Cooling medium flows are to be kept small.

The inventors propose a device is provided for cooling at least one component, especially a power machine, with at least one fluid cooling medium, with at least one cooling medium line and with a course extending along a length from an entry for the cooling medium into the component, in the component, up to an exit for the cooling medium from the component, wherein a feed is defined for the cooling medium from the entry up to an area in a middle of the length and a return is defined for the cooling medium from the area in the middle of the length up to the exit, with each cooling medium line outside the component(s) additionally passing through a cooling medium pump effecting circulation of the cooling medium in the cooling medium line and passing through a heat exchanger causing a dissipation of heat of the cooling medium heated up by the component. The proposal is characterized by a return running back to the exit along a course of the feed in the direction of the entry.

The inventors also propose a method for cooling at least one component, particularly of a power machine. The method is characterized in that an averaging of temperatures of the cooling medium in the feed with temperatures of the cooling medium in the return is undertaken.

The advantages are related to a more effective cooling. This means that a lower hotspot temperature of the power components is produced with the same cooling medium flow. Furthermore a more even temperature distribution of the power components or of the power components is effected. Furthermore the failsafe capability for the power components is improved as a result. All these stated advantages ultimately result in a greater power density of the components which reflects a current trend of many technical developments in energy and electrical power engineering.

In accordance with an advantageous embodiment, with a plurality of components the cooling medium line can have a length which runs from an entry for the cooling medium in a first component, twice through all components, up to an exit for the cooling medium from the first component, wherein the feed for the cooling medium can be defined to run once from the entry up to an area in the middle of the length through all components and the return for the cooling medium can be defined to run a further time from the area in the middle of the length back through all components up to the exit.

In accordance with a further advantageous embodiment the feed and the return, separated in the area of the middle, can be created by sections of two separate cooling medium lines, wherein a fluid cooling medium circulates in each cooling medium line separately and two circuits can be embodied, each with a cooling medium pump and a heat exchanger. This form of embodiment has the advantage of giving components enhanced failsafe capabilities since circuits are provided redundantly.

In accordance with a further advantageous embodiment the fluid cooling media can circulate in the same direction in each cooling medium line. In this way a first component is better cooled than a last component. In specific cases this can be advantageous.

In accordance with a further advantageous embodiment, in the case of one component, the feed and the return can be integrated into a cooling plate of the component.

In accordance with a further advantageous embodiment, in the case of a plurality of components, the feed can be integrated into one cooling plate respectively for each component and the return into a respective further cooling plate for each component.

In accordance with a further advantageous embodiment, in the case of a plurality of components, the two cooling plates can be created to be in surface contact with each other.

In accordance with a further advantageous embodiment, in the case of the number of components, the feed and the return can each be integrated into one cooling plate per component.

In accordance with a further advantageous embodiment the feed can be created by straight line sections arranged at right angles to one another and the return by line sections parallel thereto in each case. A distance between feed and return can be kept constant. The distance can for example be up to 15 times a diameter of the cooling medium line.

In accordance with a further advantageous embodiment the feed and the return of the cooling medium line can cover the component(s) in each case over an entire surface of the component(s).

In accordance with a further advantageous embodiment a plurality of pairs of feeds and returns can each be embodied by sections of two separate cooling medium lines, wherein a fluid cooling medium circulates separately in each case in each cooling medium line and a plurality of pairs of two circuits can be embodied. In this way the power components can be given enhanced failsafe capabilities. This means that redundant cooling circuits are provided.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 a conventional exemplary embodiment for cooling a larger power machine;

FIG. 2 a further conventional exemplary embodiment of a device for cooling the number of components, particularly of a plurality of power machines;

FIG. 3 an exemplary embodiment of a device according to the inventors' proposal, for cooling a component, particularly a power component, particularly of a power machine;

FIG. 4 a further exemplary embodiment of a device according to the inventors' proposal, for cooling a plurality of power components;

FIG. 5 a further exemplary embodiment of a device according to the inventors' proposal, for cooling a plurality of power components;

FIG. 6 a further exemplary embodiment of a device according to the inventors' proposal, for cooling a plurality of power components.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

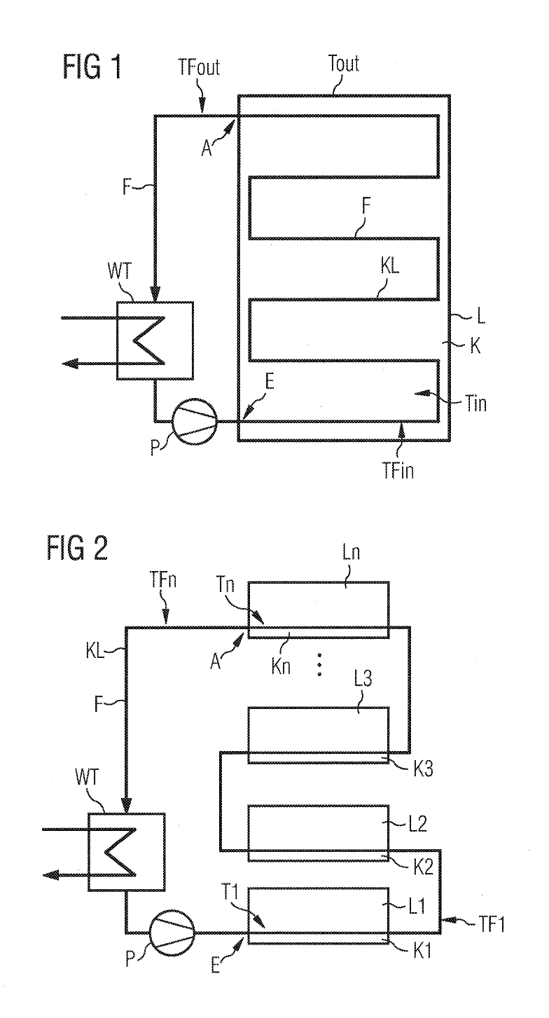

FIG. 1 shows a conventional exemplary embodiment for cooling a larger power machine L. In this embodiment WT refers to a heat exchanger for dissipating heat of a cooling medium F heated up by the component. The heat exchanger WT can also be called a return cooler. Reference character P identifies a cooling medium pump for circulation of the cooling medium F in a cooling medium line KL. Reference character K refers to a cooling plate. F refers to the cooling medium. TFin refers to a temperature of the cooling medium F in the vicinity of an entry E. TFout refers to the temperature of the cooling medium F close to an exit A. Tin refers to the temperature of the power component L close to the cooling medium entry E. Tout refers to the temperature of the power component L in the vicinity of the cooling medium exit A. In this case the temperature TFin is lower than the temperature TFout. Furthermore the temperature Tin is likewise lower than the temperature Tout. This conventional device for cooling a power component L has no return running up to an exit along a feed back in the direction of the entry. Entry E and exit A are spaced apart from each other by a large distance. Furthermore there is no return along a feed back in the direction of the entry E. The entry is designated by the reference character E. The exit is designated by the reference character A. As it flows through the cooling plate K the cooling medium F heats up, which results in there being greater cooling in the area of the entry E than at the exit A.

FIG. 2 shows a further conventional exemplary embodiment of a device for cooling a plurality of components, especially a plurality of power machines. The reference character WT refers to a heat exchanger which can also be called a return cooler. Reference character P refers to the cooling medium pump. The cooling medium pump P causes a cooling medium F to circulate in a cooling medium line KL. The heat exchanger WT causes heat to be dissipated from the cooling medium F heated up by a power component Lᵢ. L1 . . . Ln designate the power components to be cooled. K1 . . . Kn designate the cooling plates on the respective power components L1 . . . Ln. A cooling medium is likewise designated F. TF1 is the temperature of the cooling medium F after the first power component L1. TFn is the temperature of the cooling medium F after the nth power component Ln. A temperature T1 is the temperature of the first power component L1 and Tn is the temperature of the nth power component Ln. The temperature TF1 of the cooling medium F after the first power component L1 is lower than the temperature TFn of the cooling medium F after the nth power component Ln. Furthermore the temperature T1 in the first power component L1 is lower than the temperature Tn in the nth power component Ln.

FIG. 2 shows the case of a sequential cooling of a plurality of power components Li. Here the power component Ln lying at the end of the sequence of the cooling path, is the worst cooled. E refers to an entry of the cooling medium F into the first power component L1. A refers to an exit of the cooling medium F from the last power component Ln to be cooled.

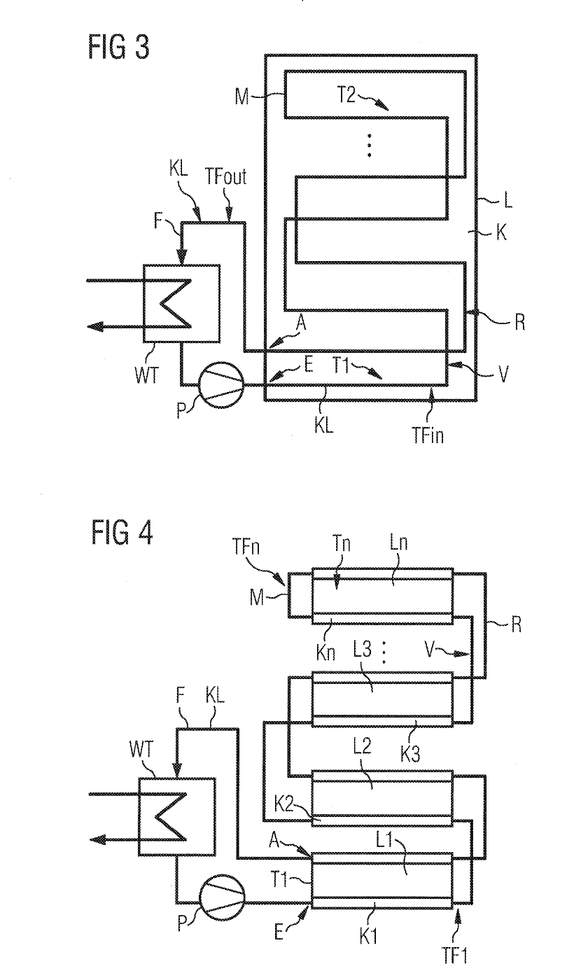

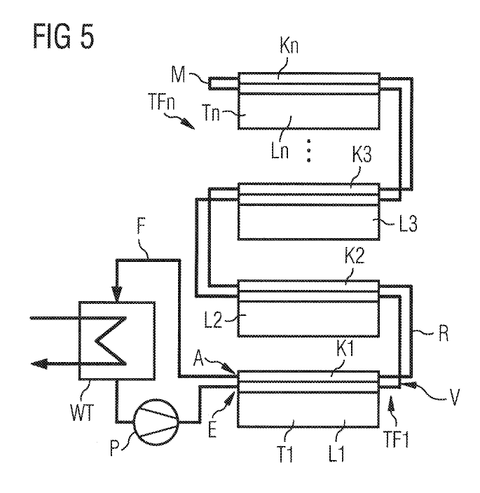

FIG. 3 shows an inventive exemplary embodiment of a device according to the inventors' proposal, for cooling a component, in particular a power component L, particularly of a power machine. WT refers to a heat exchanger for dissipating heat of a cooling medium F heated up by a power component L. L is the power component to be cooled. P refers to a cooling medium pump for circulation of the cooling medium F in a cooling medium line KL. L refers to the power component to be cooled. K refers to a cooling plate. In the cooling of power machines a cooling plate K, which dissipates the heat arising to a cooling medium F, is typically attached to a cooling surface of the power component L. E refers to an entry for the cooling medium F into the power component L. A refers to an exit of the cooling medium F from the power component to be cooled L. Entry E and exit A guide the cooling medium F into a cooling plate K or from the cooling plate K. At the exit A the cooling medium F emerges from the cooling plate K or the power component L. V refers to a feed and R refers to a return to the cooling medium F. FIG. 3 shows the cooling medium line KL with a course having a length extending from the entry E for the fluid cooling medium F into the power component L, in the component L, up to the exit A for the cooling medium F from the power component L, wherein the feed V for the cooling medium F is defined from the entry E up to an area in a middle M of the length and the return R for the cooling medium F is defined from the area in the middle M of the length up to the exit A. Outside the power component L the cooling medium KL is routed through a cooling medium pump P and a heat exchanger WT. The return R runs along the feed V in the direction of the entry E to the exit A. TFin refers to the temperature of the cooling medium F at entry E and TFout refers to the temperature of the cooling medium F at exit A. In this case the temperature TFin is lower than the temperature TFout. T1 refers to the temperature close to the cooling medium entry E. T2 refers to the temperature in the area of the middle M of the length of the path from the entry E for the fluid cooling medium F into the component L, in the component L, up to the exit A for the cooling medium F from the power component L. The arrangement of feed V and return R means that the temperatures T1 and T2 are approximately the same. In this way an even temperature of the power component L is generated. In the case of a power component L the feed V and the return R can be integrated into a cooling plate K of the component. The feed V can be created by straight sections of the route arranged at right angles to one another and the return R by route sections parallel thereto in each case. The distance between the feed V and the return R can typically be up to 20 times a cooling medium line diameter. This distance can also be predetermined by a thickness of power components to be cooled (see FIG. 4).

FIG. 4 shows a further exemplary embodiment of a device for cooling a plurality of power components Li. WT refers to a heat exchanger or return cooler for dissipating heat of a cooling medium F heated up by the power component Li. P refers to a cooling medium pump for circulation of the cooling medium F in a cooling medium line KL. L1 . . . Ln designate the power components Li to be cooled. K1 . . . Kn designate cooling plates. F refers to the cooling medium. KL refers to a cooling medium line. E refers to an entry for the cooling medium F into a first power component L1. A refers to an exit for the cooling medium F from the first power component L1. A feed V for the cooling medium F is defined from the entry E up to an area in a middle M of the length once through all power components Li and a return R is defined for the cooling medium F back again through all power components Li a further time up to the exit A. TF1 is the temperature of the cooling medium F after the first power element L1. TFn is the temperature of cooling medium F after the nth power component Ln. T1 refers to the temperature of the first power component L1 and Tn refers to the temperature of the nth Ln. In this case the temperature TF1 of the cooling medium F after the first power component L1 is lower than the temperature TFn of the cooling medium F after the nth power component Ln.The temperature T1 of the first power component L1 is now approximately the same as the temperature Tn of the nth power component Ln.

In accordance with FIG. 3 and FIG. 4 a feed V and a return R are used for cooling power machines. The course of the feed V and the return R of the cooling medium F, through a counter-flow interconnection, allows the feed temperature and the return temperature of the cooling medium F to be averaged. This type of interconnection can advantageously be implemented both for the cooling of an individual power component in accordance with FIG. 3 and also for a series of a plurality of power components to be cooled (see FIG. 4). In accordance with FIG. 4, in the case of a plurality of power components Li, the feed V is integrated into one cooling plate K per component L in each case and the return is integrated into a another cooling plate K for each component L in each case. An interconnection with two separate cooling plates in accordance with FIG. 4 can be realized.

FIG. 5 shows a further exemplary embodiment of a device for cooling a plurality of power components Ln. In this example the reference characters of FIG. 5 correspond to the reference characters of FIG. 4. Unlike FIG. 4, in FIG. 5, the two cooling plates K are created to be in surface contact with each other for each power component L. In this way the temperature TF1 of the cooling medium F after the first power component L1 corresponds to the temperature TFn of the cooling medium F after the nth power component Ln. Furthermore the temperature T1 of the first power component L1 corresponds to the temperature Tn of the nth power component Ln. In accordance with a further form of embodiment, in the case of the number of power components Li, as is shown in accordance with FIG. 5, the feed V and the return R by each integrated into one cooling plate K for each power component Li. In accordance with FIG. 5 the cooling plates K each have a separate feed V and a separate return R.

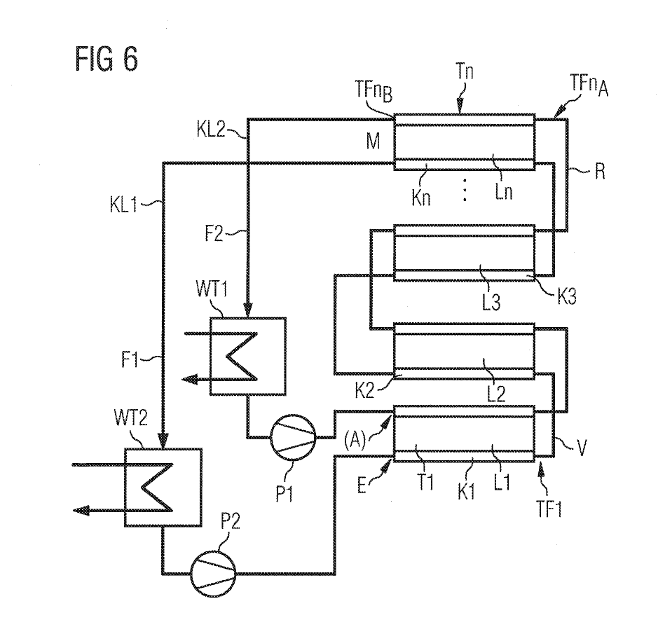

In accordance with FIG. 6 a further embodiment of a device for cooling a plurality of power components Li is presented. In this embodiment the same reference characters of FIG. 6 refer to the same elements in each case as those in FIG. 4. FIG. 6 represents a further circuit variant with two separate cooling medium parts which make redundant cooling possible, wherein two separate flows of cooling medium F1 and F2 have separate, redundant cooling medium pumps P1 and P2, and also heat exchangers WT1 and WT2 available to them.

In accordance with FIG. 6 the feed V and the return R are separated in the area of the middle M compared to FIG. 4, so that sections of two separate cooling medium lines KL1 and KL2 are embodied, wherein a fluid cooling medium F1 and F2 circulates separately in each cooling medium line KL1 and KL2 and two redundant circuits are embodied, each with a cooling medium pump P and a heat exchanger WT. In this way an enhanced failsafe capability for power components L is created. In accordance with FIG. 6 two forms of embodiment are possible. In accordance with a first form of embodiment the fluid cooling media F1 and F2 circulate in opposite directions. In this way the temperature T1 of the first power component L1 and the temperature Tn of the nth power component Ln correspond to one another. Furthermore the temperatures TF1 of the cooling medium F1 after the first power component L1 and the temperature TFn_{A} of the cooling medium F2 after the nth power component Ln are equal. In accordance with this form of embodiment, unlike in FIG. 6, the cooling medium F2 circulates in a clockwise direction. The cooling medium F1 circulates in a counterclockwise direction.

FIG. 6 represents the second form of embodiment in which the fluid cooling media F1 and F2 in each cooling medium line KL1 and KL2 circulate in the same direction, in accordance with FIG. 6 both in a counterclockwise direction. In accordance with this form of embodiment the temperature T1 of the first power component L1 is then lower than the temperature Tn of the nth power component Ln. Furthermore the temperature TF1 of the cooling medium F1 after the first power component L1 is lower than the temperature TFn_{B} of the cooling medium F2 after the nth power component Ln.

According to further exemplary embodiments in accordance with FIG. 6, in a first case the feed V can be integrated into a cooling plate K for each power component Li in each case and the return R can be integrated into a further cooling plate K for each power component Li in each case. Furthermore for each power component Li the two cooling plates K can be created to be in surface contact with one another. In accordance with a further embodiment the feed V and the return R can together be integrated into one cooling plate K for each power component Li in each case.

A plurality of pairs of feeds V and returns R can each be embodied by sections of two separate cooling medium lines KL1 and KL2, wherein a respective fluid cooling medium F1 and F2 circulates separately in each cooling medium line KL1 and KL2 and a plurality of pairs of two circuits can be embodied.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-12. (canceled)

13. A device for cooling at least one component, comprising:
a fluid cooling medium;
at least one cooling medium line to carry the cooling medium, the cooling medium line having a length extending through the component, the cooling medium line having a feed portion that extends from a cooling medium entry to an area in a middle of the length, the cooling medium line also having a return portion that extends from the area in the middle of the length up to a cooling medium exit, the return portion running back along the feed portion up to the cooling medium exit;
a cooling medium pump provided outside the component, that causes the cooling medium to circulate in the cooling medium line; and
a heat exchanger provided outside the component, to dissipate heat from the cooling medium, that was collected from the component.

14. The device as claimed in claim 13, wherein
a plurality of components are cooled such that the cooling medium line extends twice through all components,
the feed portion of the cooling medium line extends from the entry of a first component, through all components up to the area in the middle of the length, and
the return portion of the cooling medium line extends from a last component, through all components up to the exit in the first component.

15. The device as claimed in claim 13, wherein
the device has first and second separate cooling medium lines, each having a cooling medium pump and a heat exchanger such that two separate cooling circuits are defined.

16. The device as claimed in claim 15, wherein each cooling medium line has both a feed portion and a return portion.

17. The device as claimed in claim 16, wherein
The cooling media circulate in the same direction in the first and second cooling medium lines.

18. The device as claimed in claim 15, wherein
the first cooling medium line forms the feed portion and extends from the cooling medium entry to the area in the middle of the length, and
the second cooling medium line forms the return portion and extends from the area in the middle of the length up to the cooling medium exit.

19. The device as claimed in claim 13, wherein
each component is provided on a cooling plate, and
the feed and return portions are integrated into the cooling plate.

20. The device as claimed in claim 14, wherein
each component is provided on at least two cooling plates,
the feed portion is integrated into a first of the cooling plates, and
the return portion is integrated into a second of the cooling plates.

21. The device as claimed in claim 20, wherein
the first and second cooling plates are in surface contact with one another.

22. The device as claimed in claim 14, wherein
each component is provided on a cooling plate, and
for each component, the feed and return portions are integrated into the cooling plate for the component.

23. The device as claimed in claim 13, wherein
the feed portion is created by straight route sections arranged at right angles to one another, and
the return portion is created by route sections in parallel to the route sections of the feed portion.

24. The device as claimed in claim 13, wherein
the feed portion and the return portion of the cooling medium line, cool each component, over an entire surface area of the component.

25. A method for cooling at least one component, comprising:
providing a cooling medium line having a length extending through the component, the cooling medium line having a feed portion that extends from a cooling medium entry to an area in a middle of the length, the cooling medium line also having a return portion that extends from the area in the middle of the length up to a cooling medium exit, the return portion running back along the feed portion up to the cooling medium exit;
pumping a cooling medium through the cooling medium line;
using a heat exchanger provided outside the component, to dissipate heat from the cooling medium, that was collected from the component; and
averaging a temperature of the cooling medium in the feed portion with a temperature of the cooling medium in the return portion.
